(19) United States
(12) Patent Application Publication
(10) Pub. No.: US 2004/0187308 A1
(43) Pub. Date: Sep. 30, 2004

(54) Method for fixing an electrical element and a module with an electrical element fixed thus

(76) Inventor: Holger Haussmann, Metzingen (DE)

Correspondence Address: Michael J Striker, Striker Striker & Stenby, 103 East Neck Road, Huntington, NY, 11743, US

(21) Appl. No.: 10/487,315

(22) PCT Filed: Aug. 17, 2002
(86) PCT No.: PCT/DE02/03036

(30) Foreign Application Priority Data
Aug. 24, 2001 (DE) 101-41-603.2

(51) Int. Cl. H05K 3/30

(52) U.S. Cl. 29/832; 29/837; 29/838

(57) ABSTRACT

A method for fixing an electrical element, in particular a diode (20), using an insert, in particular a diode socket (26) in a support body (23), is disclosed. The insert, in particular, the diode socket (26), is applied in an opening (35) in the support body (23). Said method is characterized in that, in a further step, material of the support body (23) around the insert is forced into the insert, in order to achieve a strong connection between the electrical element and the support body (23).

### BACKGROUND INFORMATION

The invention relates to a method for fixing an electrical element, in particular a diode, and a module according to the general class of the independent claim. It is made known in European patent publication 0 329 722 B1 that electrical elements, configured as diodes, for rectifier devices for three-phase generators are inserted, via pressing, into receptacle holes in support bodies. To accomplish this, a bore is created in a support body, which interacts with a diode socket to produce an interference fit. The diode socket and the diode are then pressed into said bore. The disadvantage of this configuration is that the bore must be relatively small in order to ensure that the diode is held securely in the bore and to ensure sufficient heat transfer from the diode to the support body. Associated with this is the fact that the high press-in forces can result in deformation of the diode socket and, therefore, to preliminary damage of the installed diode chip. Diodes that have been pressed in in this manner can fail relatively early. Moreover, mechanical tolerances at the diode socket and in the bore result in transitions between diodes and support bodies that are not entirely thermally optimal. This can result in high temperatures forming at the diodes and, as a result, operating failure.

### ADVANTAGES OF THE INVENTION

The method according to the invention for fixing an electrical element, in particular a diode, having the features of the main claim, has the advantage that the pressing between insert and bore in the support body can be further reduced, yet a good hold of the electrical element in the support body and an equally good thermal transition between electrical element and support body can be achieved.

The failure rates of electrical elements is reduced, because the press-in forces are reduced.

Advantageous further developments of the method for fixing an electrical element according to the main claim are possible due to the measures listed in the subclaims.

If material of the support body is forced into the insert by a radial force using a punch, the method is simple and economical.

If the punch has a generally conical shape, the effect of the displacement of the material into the insert is enhanced particularly well, and punching forces can be reduced. As a result, the amount of energy used in the production method is reduced, and the reliability of the displacement process is improved. If only the punch has a generally conical shape, material can be displaced in the area of the end surface, i.e., on the end surface of the insert that is furthest away from the connection wire. This is an area that, in the case of a diode, for example, is relatively far away from the diode chip, so that the danger of destroying said diode chip is particularly minimal here.

If the axial force of the punch is absorbed by a counter punch, the position of the support body before and after the assembly procedure in the direction of the connection wire does not have to be changed, since the two punches press on the support body at the same time. A support body that is annular in shape, for example, need only be turned around its ring axis.

A uniform displacement around the insert is achieved by the fact that the punch and counter punch are both configured annular in shape.

A displacement of the material of the support body that is particularly uniform and central, i.e., symmetrical in terms of the plate strength of the support body, is achieved by the fact that the punch and the counter punch have a generally conical shape.

A module for electrical machines that is produced according to the individual method steps has particularly reliable support bodies with electrical elements, since the electrical elements undergo a particularly minimal amount of preliminary damage.

### DRAWING

Exemplary embodiments of methods, according to the invention, for fixing electrical elements, in particular power diodes, in support bodies, and a module for electrical machines with electrical elements pressed in according to the method are shown in the drawing.

FIG. 1 shows a power diode before it is pressed into a support body,

FIG. 2 shows the power diode pressed into the support body,

FIG. 3 shows the power diode before material is forced into the diode socket,

FIG. 4 shows how material is forced into the diode socket by the punch,

FIG. 5 shows a variant of the method, whereby the punch and the counter punch are both generally conical in shape,

FIG. 6 shows a rectifier module for electrical machines with a support body in which at least one diode is fixed according to the method according to the invention.

### DESCRIPTION

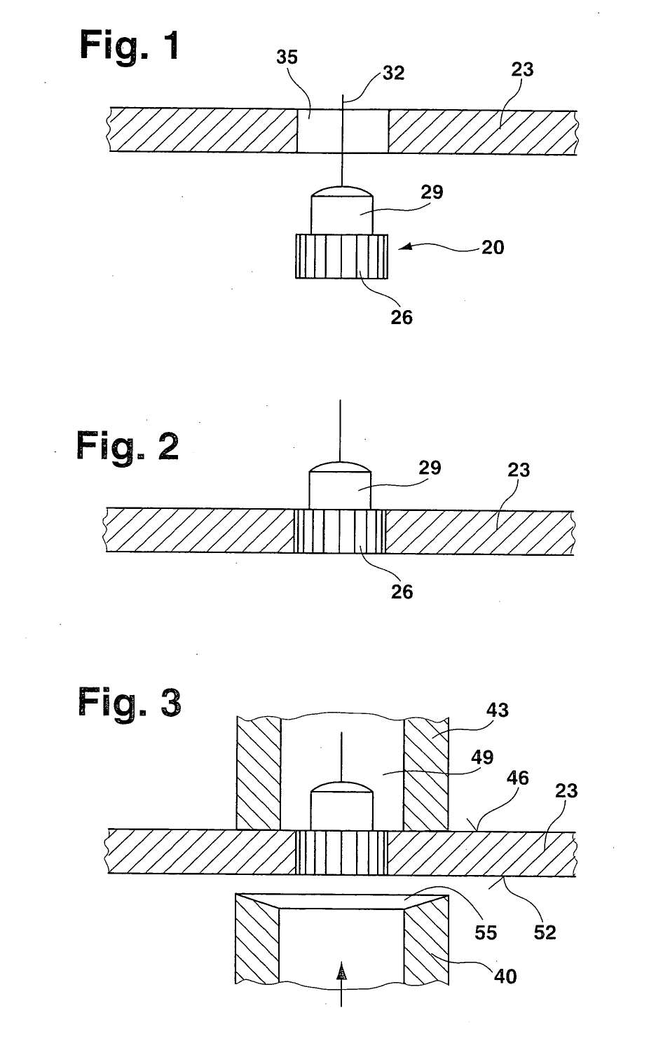

A diode, which is configured as a power diode 20, and a support body 23 are shown in FIG. 1. Power diode 20 consists of three different sections. The first section is the insert that is configured as diode socket 26—sometimes also referred to as a heat sink. The second section is the actual rectifier part 29. Diode head lead 32, as the connection wire, extends out of said rectifier module and forms the third section. Support body 23 has an opening 35 that is typically configured as a cylindrical bore. Diode socket 26 is usually configured as a cylindrical part and includes ribbing that is shown on its outer circumference. The diameter of opening 35 is usually slightly smaller than the diameter of diode socket 26, so that a considerable amount of force is required to press power diode 20, with its diode socket 26, into opening 35. In the case of the present invention, in the first exemplary embodiment, opening 35 is still configured with a diameter that is smaller than that of diode socket 26. However, the fit dimension between opening 35 and diode socket 26 is modified in such a manner that the amount of force required to install diode socket 26 in opening 35 is reduced compared to the related art.

In the first step, power diode 20, with its diode socket 26, is pressed into opening 35, resulting in the condition shown in FIG. 2.

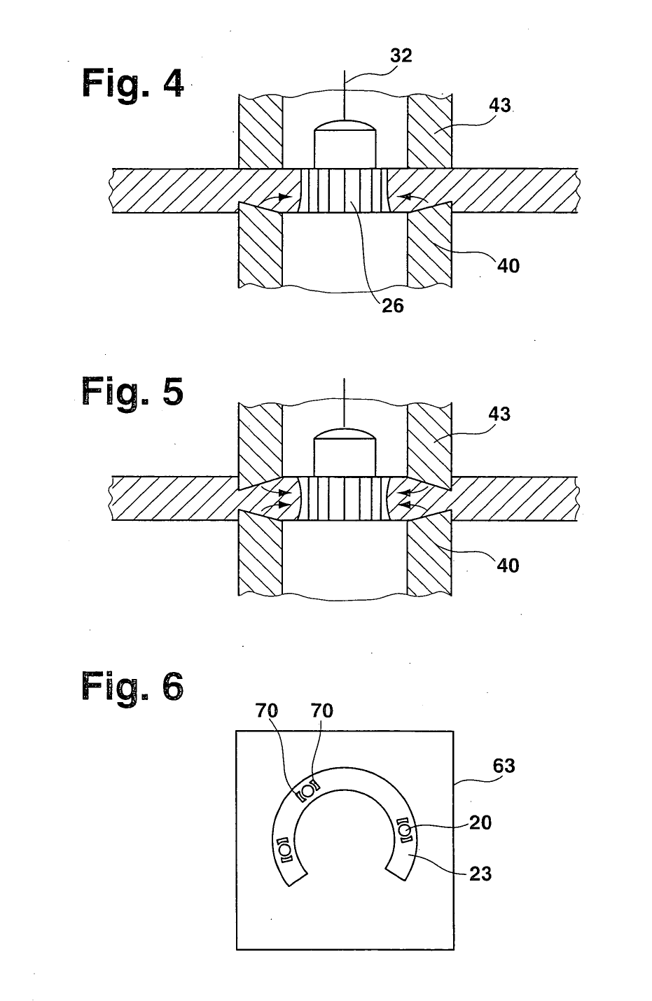

With reference to FIGS. 3 and 4, it will now be explained hereinbelow how material of the support body 23 around diode socket 26 is forced into diode socket 26 in a further step. To this end, a punch 40 and a counter punch 43 are required in a first exemplary embodiment. Support body 23 with power diode 20 is brought to rest against counter punch 43 via a surface 46 of support body 23. Counter punch 43 has a generally hollow-cylindrical shape, whereby rectifier part 29 and diode head lead 32 extend inside a hollow-cylindrical part 49. Support body 23 has a counter surface 52 that is opposite to surface 46. If support body 23 rests against counter punch 43, material of support body 23 is forced into diode socket 26 using punch 40, which is also configured hollow-cylindrical in shape. To this end, punch 40 is moved toward counter surface 52, a generally conical, e.g., hollow-conical shape 55 of punch 40 ultimately penetrates the material of support body 23, FIG. 4, and displaces material of support body 23 in the direction of an axis 58 of power diode 20 using the pitch of the conical shape of punch 40. A radial force is produced by conical shape 55 of punch 40, which ultimately brings about the displacement of material into diode socket 26. A general axial force of punch 40, which is ultimately required to displace material, is absorbed by counter punch 43.

In deviation from the exemplary embodiment according to FIG. 3 and FIG. 4, a second exemplary embodiment according to FIG. 5 will be discussed briefly.

In this case, a punch 40 and a counter punch 43 bring about the displacement of material of support body 23 into diode socket 26 in similar fashion. In contrast to the previous exemplary embodiment, counter punch 43 is configured exactly like punch 40, i.e., counter punch 43 also has a generally conical or hollow-cylindrical shape 55, which is suited to applying a radial force with which material of support body 23 is forced into diode socket 26 from counter punch 43 outward. In a fashion that is similar to the exemplary embodiment according to FIG. 3 and FIG. 4, support plate 23 is first brought to rest against counter punch 43 in this case as well, and punch 40 is moved toward counter surface 52. Punch 40, with its conical shape 55, penetrates the material of support body 23. According to the general principle that, for every action there is an equal and opposite reaction, and due to the conical shape 55 of counter punch 43, counter punch 43 also penetrates the material of support body 23 with its conical shape 55, thereby also bringing about a displacement of the material of support body 23 from surface 46 into diode socket 26. Finally, as with the exemplary embodiment according to FIG. 3 and FIG. 4, both punch 40 and counter punch 43 are lifted away from support body 23 and, ultimately, support body 23 with fully-installed power diode 20 is removed from the fabrication device.

In principle, it is not necessary for punch 40 or counter punch 43 to both have a conical or hollow-conical shape 55. In principle, it is possible to displace the material of support body 23 into diode socket 26 using a punch 40 that is configured exactly like counter punch 43 in FIG. 3, so that two basically blunt punches 40, 43 enable a displacement of material from surface 46 as well as counter surface 52.

FIG. 6 shows a rectifier module 65 in a schematic representation of a module of the type required for three-phase generators for motor vehicles. Rectifier module 65 includes at least one support body 23 on which a power diode 20 is mounted, whereby the at least one power diode 20 is fixed according to one of the methods described hereinabove. Power diodes 20 are surrounded by obvious pinches at a plurality of locations.

As an alternative, the dimension of opening 35 and the diameter of diode socket 26 can also be configured as a clearance fit. The pressing between diode 20 and support body 23 is not produced until the support body material is displaced. The displacement can also be carried out in accordance with one of the exemplary embodiments described previously.

What is claimed is:

1. A method for fixing an electrical element, in particular a diode (20), using an insert, in particular a diode socket (26) in a support body (23), whereby the insert is applied in an opening (35) in the support body (23), wherein, in a further step, material of the support body (23) around the insert is forced into the insert, in order to achieve a strong connection between the electrical element and the support body (23).

2. The method as recited in claim 1, wherein the material is forced into the insert by radial force, using a punch (40).

3. The method as recited in claim 1, wherein the punch (40) has a generally conical shape (55).

4. The method as recited in claim 2, wherein axial force of the punch (40) is absorbed by a counter punch (43).

5. The method as recited in claim 2, wherein at least one of the punches (40, 43) is configured annular in shape.

6. The method as recited in claim 4, wherein the counter punch (43) also has a generally conical shape (55) and, as a result, it also forces material into the insert using radial force.

7. A module for electrical machines with at least one electrical element, in particular support body (23) that supports a diode (20), wherein the at least one electrical element is fixed according to one of the method steps described in claim 1.

8. The module according to the preamble of claim 7, wherein the support body (23) has a pinch in at least one location around the electrical element.
